(19) United States
(12) Patent Application Publication
(10) Pub. No.: US 2025/0253103 A1
(43) Pub. Date: Aug. 7, 2025

(54) HYBRID SOLID-STATE ELECTRICAL SWITCH

(71) Applicant: HONEYWELL INTERNATIONAL INC., Charlotte, NC (US)

(72) Inventors: HUSSAIN -, Charlotte, NC (US); Hari Suriya REDDY, Charlotte, NC (US); Alok RANJAN, Charlotte, NC (US)

(21) Appl. No.: 19/029,338

(22) Filed: Jan. 17, 2025

(30) Foreign Application Priority Data
Feb. 1, 2024 (IN) 202411006721

(51) Int. Cl. H01H 3/02; H01H 9/54

(52) U.S. Cl. CPC H01H 3/02; H01H 9/541

(57) ABSTRACT

A hybrid solid-state electrical switch comprising a plunger, a switch actuation sensor configured to (i) determine actuation or non-actuation of the plunger and (ii) generate one or more actuation signals based on the determined actuation or non-actuation, one or more input/output terminals, and a switching circuit that is configured to perform switching operations on the one or more input/output terminals based on the one or more actuation signals.

### CROSS-REFERENCE TO RELATED APPLICATION

This application claims priority pursuant to 35 U.S.C. 119(a) to the Indian application Ser. No. 202411006721, filed Feb. 1, 2024, which application is incorporated herein by reference in its entirety.

### TECHNICAL FIELD

Various embodiments of the present disclosure relate to non-contact solid-state electrical switches, and more particularly to sensor actuated semiconductor switches.

### BACKGROUND

Traditional electromechanical switches are commonly used for breaking/making circuits. However, electromechanical switches have limited lifecycles, require precious metal contacts, and are prone to contact failures such as contact weld, arcing, oxidation and other mechanical failures. Electromechanical switches also suffer from dead band, dead make and break, higher response times, switch bounce. Applicant has identified many technical deficiencies and limitations associated with conventional electromechanical switches.

### BRIEF SUMMARY

Various embodiments described herein relate to hybrid solid-state electrical switches.

In accordance with various embodiments of the present disclosure, a hybrid solid-state electrical switch comprises a plunger; a switch actuation sensor configured to (i) determine actuation or non-actuation of the plunger and (ii) generate one or more actuation signals based on the determined actuation or non-actuation; one or more input/output terminals; and a switching circuit that is configured to perform switching operations on the one or more input/output terminals based on the one or more actuation signals.

In some embodiments, the switching operations are associated with a single pole, double throw switch. In some embodiments, the one or more input/output terminals comprise a common input voltage and one or more electrical loads. In some embodiments, the one or more electrical loads comprise a normally closed-circuit load and a normally open circuit load. In some embodiments, the switching circuit is configured to direct the common input voltage to the normally closed-circuit load based on the one or more actuation signals comprising a signal representative of the plunger being unactuated; and direct the common input voltage to the normally open circuit load based on the one or more actuation signals comprising a signal representative of the plunger being actuated.

According to another embodiment, a hybrid solid-state electrical switch comprises a plunger; a switch actuation sensor configured to (i) determine actuation or non-actuation of the plunger and (ii) generate one or more actuation signals based on the determined actuation or non-actuation; one or more input/output terminals; a switching circuit that is configured to perform switching operations on the one or more input/output terminals; and an isolated gate driver coupled to the switching circuit, the isolated gate driver is configured to (i) receive the one or more actuation signals and (ii) control operation of the switching circuit based on the one or more actuation signals.

In some embodiments, the switch actuation sensor is configured to determine the actuation or non-actuation of the plunger based on optical or electromagnetic changes caused by movement of the plunger an unactuated position to an actuated position. In some embodiments, the switch actuation sensor comprises an infrared sensor, a photodetector sensor, or an optical sensor. In some embodiments, the switch actuation sensor comprises a Hall-effect-based sensor or an anisotropic magnetoresistance sensor. In some embodiments, the isolated gate driver is configured to open and close one or more portions of the switching circuit based on the one or more actuation signals.

According to another embodiment, a hybrid solid-state electrical switch comprises a switch actuation sensor configured to (i) determine actuation or non-actuation of a mechanical device and (ii) generate one or more actuation signals based on the determination of the actuation or non-actuation; an isolated gate driver configured to generate a gate drive based on the one or more actuation signals; a common terminal, a normally closed terminal, and a normally open terminal; and a transistor switch coupled to the common terminal, the normally closed terminal, and the normally open terminal, the transistor switch is configured to open and close one or more circuits between the common terminal and one of the normally closed terminal or the normally open terminal based on the gate drive.

In some embodiments, the one or more actuation signals are associated with an enable signal comprising a non-zero value that is representative of an actuation of the mechanical device. In some embodiments, the one or more actuation signals are associated with an enable signal comprising a zero value that is representative of a non-actuation of the mechanical device. In some embodiments, the transistor switch comprises one or more of bipolar junction transistors, integrated gate-commutated thyristors (IGCT), reverse blocking IGCTs, insulated gate bipolar transistors, metal-oxide-semiconductor field-effect transistors (MOSFETs), gate turn-off thyristors, MOSFET-controlled thyristors, silicon carbide switching devices, or gallium nitride switching devices. In some embodiments, the isolated gate driver is configured to cause the transistor switch to drive the normally open terminal with the common terminal based on the one or more actuation signals comprising a non-zero value. In some embodiments, the isolated gate driver is configured to cause the transistor switch to drive the normally closed terminal with the common terminal based on the one or more actuation signals comprising a zero value. In some embodiments, the transistor switch comprises a PNP MOSFET array and a NPN MOSFET array. In some embodiments, the PNP MOSFET array and the NPN MOSFET array are configured in opposite bias.

The foregoing illustrative summary, as well as other exemplary objectives and/or advantages of the disclosure, and the manner in which the same are accomplished, are further explained in the following detailed description and its accompanying drawings.

### BRIEF DESCRIPTION OF THE DRAWINGS

The description of the illustrative embodiments may be read in conjunction with the accompanying figures. It will be appreciated that, for simplicity and clarity of illustration, elements illustrated in the figures have not necessarily been drawn to scale, unless described otherwise. For example, the dimensions of some of the elements may be exaggerated relative to other elements, unless described otherwise. Embodiments incorporating teachings of the present disclosure are shown and described with respect to the figures presented herein, in which:

FIG. 1 illustrates a hybrid solid-state electrical switch in accordance with various embodiments of the present disclosure;

FIG. 2 is a cross-sectional view of a hybrid solid-state electrical switch in accordance with various embodiments of the present disclosure;

FIG. 3 is a schematic block diagram of a circuit board in accordance with various embodiments of the present disclosure; and,

FIG. 4 is a schematic diagram of a hybrid solid-state electrical switch in accordance with various embodiments of the present disclosure.

### DETAILED DESCRIPTION

Some embodiments of the present disclosure will now be described more fully hereinafter with reference to the accompanying drawings, in which some, but not all embodiments of the disclosure are shown. Indeed, these disclosures may be embodied in many different forms and should not be construed as limited to the embodiments set forth herein; rather, these embodiments are provided so that this disclosure will satisfy applicable legal requirements. Like numbers refer to like elements throughout.

As used herein, terms such as “front,” “rear,” “top,” etc., are used for explanatory purposes in the examples provided below to describe the relative position of certain components or portions of components. Furthermore, as would be evident to one of ordinary skill in the art in light of the present disclosure, the terms “substantially” and “approximately” indicate that the referenced element or associated description is accurate to within applicable engineering tolerances.

As used herein, the term “comprising” means including but not limited to and should be interpreted in the manner it is typically used in the patent context. Use of broader terms such as comprises, includes, and having should be understood to provide support for narrower terms such as consisting of, consisting essentially of, and comprised substantially of.

The phrases “in one embodiment,” “according to one embodiment,” and the like generally mean that the particular feature, structure, or characteristic following the phrase may be included in at least one embodiment of the present disclosure, and may be included in more than one embodiment of the present disclosure (importantly, such phrases do not necessarily refer to the same embodiment).

The word “example” or “exemplary” is used herein to mean “serving as an example, instance, or illustration.” Any implementation described herein as “exemplary” is not necessarily to be construed as preferred or advantageous over other implementations.

If the specification states a component or feature “may,” “can,” “could,” “should,” “would,” “preferably,” “possibly,” “typically,” “optionally,” “for example,” “often,” or “might” (or other such language) be included or have a characteristic, that a specific component or feature is not required to be included or to have the characteristic. Such a component or feature may be optionally included in some embodiments, or it may be excluded.

As described above, there are many technical deficiencies and limitations associated with conventional electromechanical switches. Additionally, there are limitations in adapting electromechanical switches to newer and “smart” applications. For example, electromechanical switches cannot be integrated with newer generation technology requirements, such as data collection, switch failure detection, or switch life monitoring. Thus, there is a need for switches that are capable of working with applications which require precise, reliable, high lifecycles, and an ability to integrate with, for example, Internet of Things (IoT) devices, remote monitoring/operation capability, and a platform for data collection and analysis.

Various example embodiments of the present disclosure overcome such technical deficiencies and limitations in electromechanical switches and provide various technical advancements and improvements. According to various embodiments, a hybrid solid-state electrical switch is provided. In some embodiments, a hybrid solid-state electrical switch comprises a switch actuation sensor and a semiconductor-based switching circuit. In some embodiments, the switch actuation sensor comprises an infrared (IR), photodetector, or optical sensor that is configured to detect actuation of a plunger based on light detection. In some embodiments, the switch actuation sensor comprises a Hall-effect-based/anisotropic magnetoresistance (AMR) sensor that is configured to detect actuation of the plunger based on magnetic field detection.

In some embodiments, a hybrid solid-state electrical switch is configured to operate in a single pole, double throw (SPDT) configuration. In some embodiments, the SPDT configuration is provided by a semiconductor-based switching circuit that comprises a pair of transistors, such as metal-oxide-semiconductor field-effect transistors (MOSFETs) that are biased in opposite NPN and PNP configurations. In some embodiments, the plunger comprises a plunger, wherein upon application of force on the plunger causes a displacement of the plunger that this detectable by the switch actuation sensor (e.g., via an interruption of light or a magnetic field). In some embodiments, the switch actuation sensor is configured to detect a displacement of the plunger and generate a signal that controls the isolated gate driver. In some embodiments, the isolated gate driver may be configured to turn on and off the pair of transistors in alternating fashion due to opposite biasing of the transistors.

Hybrid solid-state electrical switches, as disclosed herein, resolve deficiencies in existing electromechanical switches. For example, the disclosed hybrid solid-state electrical switches combine electronic switching with mechanical actuation without use of electrical contacts thereby preventing wear and tear and arcing as no electrical contacts are used and avoids usage of precious metal contacts. As such, the disclosed hybrid solid-state electrical switches may comprise higher lifecycles, e.g., a few orders of magnitude greater than conventional electromechanical switches. The disclosed hybrid solid-state electrical switches may also comprise higher switching frequency and faster response times compared to conventional electromechanical switches. In some embodiments, a hybrid solid-state electrical switch is configured to communicate with networked and/or computing devices (e.g., IoT) and provide features, such as data collection, remote operation capability, switch condition monitoring, and switch failure detection.

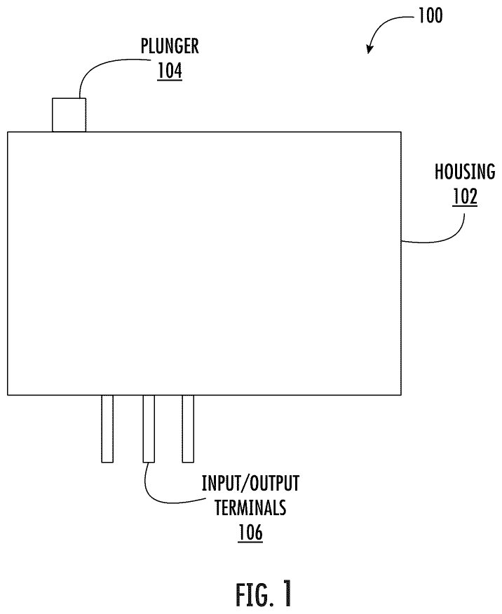

Referring now to FIG. 1, a hybrid solid-state electrical switch 100 is provided in accordance with various embodiments of the present disclosure. As depicted in FIG. 1, hybrid solid-state electrical switch 100 comprises a plunger 104 disposed in an aperture of housing 102. Plunger 104 may comprise a mechanical component that may be moved between an unactuated state and an actuated state. Plunger 104 may be physically moved from an unactuated position to an actuated position via application of vertical pressure upon the plunger 104.

In some embodiments, housing 102 includes a switch actuation sensor. The switch actuation sensor may be configured to (i) determine actuation or non-actuation of plunger 104 (e.g., between the unactuated state and the actuated state) and (ii) generate actuation signals representative of whether plunger 104 is in the unactuated position or the actuated position. In some embodiments, the actuation signals generated by the switch actuation sensor are used to control operation of a switching circuit. As such, plunger 104 need not make contact with a circuit (e.g., input/output terminals 106) to switch the circuit.

In some embodiments, housing 102 further includes a switching circuit that is configured to perform switching operations based on actuation of plunger 104. In some embodiments, the input/output terminals 106 comprise a plurality of connection contacts to the switching circuit. For example, the input/output terminals 106 may be used to couple a common input voltage and one or more electrical loads (e.g., circuits) to the switching circuit. As such, switching may be performed on the input/output terminals 106 based on actuation signals generated by the switch actuation sensor. According to various embodiments of the present disclosure, the switching circuit is configured as (e.g., performs switching operations of) a given type of electrical switch, such as, but not limited to, a SPDT switch, on the input/output terminals 106.

In some example embodiments, the input/output terminals 106 may comprise an input voltage/current (common), a normally closed-circuit load, and a normally open circuit load. In some example embodiments, the switching circuit of the hybrid solid-state electrical switch 100 is configured to (i) direct the input voltage/current to the normally closed-circuit load based on actuation signals representative of the plunger 104 being unactuated or (ii) direct the input voltage/current to the normally open circuit load based on actuation signals representative of the plunger 104 being actuated. The hybrid solid-state electrical switch 100 may also be configured to operate as double pole, double throw (DPDT) switches.

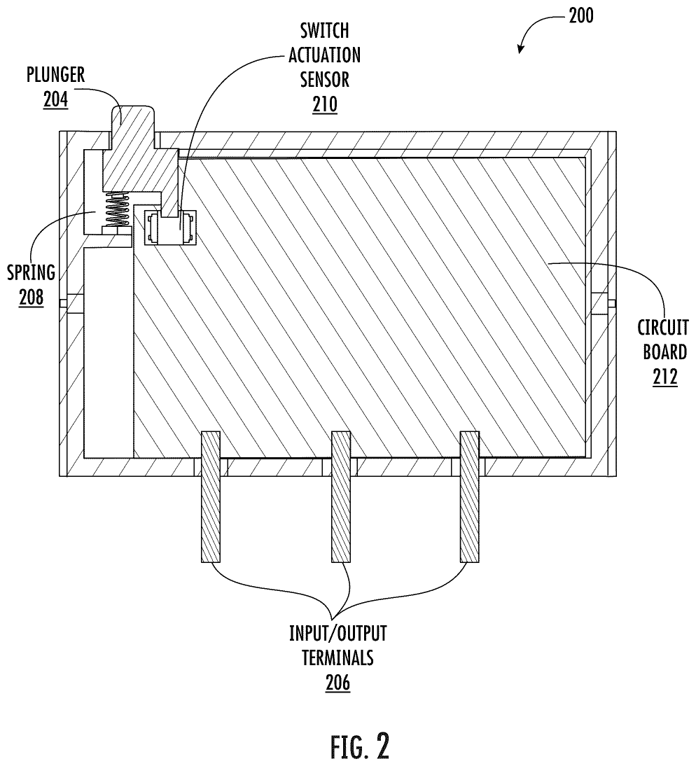

FIG. 2 is a cross-sectional view of a hybrid solid-state electrical switch 200 in accordance with various embodiments of the present disclosure. Hybrid solid-state electrical switch 200 comprises plunger 204 that is seated on spring 208. Absent a force applied to plunger 204, plunger 204 is held in an unactuated position by spring 208. The plunger 204 may be actuated by applying an operating force to plunger 204 to overcome a resistance provided by spring 208.

Circuit board 212 comprises switch actuation sensor 210 that is configured to determine actuation or non-actuation of plunger 204 based on optical or electromagnetic changes caused by movement of plunger 204 between an unactuated position and an actuated position. In some embodiments, the switch actuation sensor 210 comprises an IR, photodetector, or optical sensor that is configured to detect changes in light caused by pressing the plunger 204. For example, a light deflector may be coupled to plunger 204 and actuating plunger 204 may comprise a change in vertical position of plunger 204 that interrupts or changes light rays detected by switch actuation sensor 210 thereby causing switch actuation sensor 210 to generate an actuation signal associated with the actuation of the plunger 204. In some embodiments, the switch actuation sensor 210 comprises a Hall-effect-based/AMR sensor that is configured to detect changes in magnetic field caused by pressing the plunger 204. For example, a magnetic component may be coupled to plunger 204 and actuating plunger 204 may comprise a change in a magnetic field detected by switch actuation sensor 210 thereby causing switch actuation sensor 210 to generate an actuation signal associated with the actuation of plunger 204.

Circuit board 212 may further comprise circuitry configured to receive actuation signals from switch actuation sensor 210 and provide switching functionality on input/output terminals 206 based on the actuation signals. In some embodiments, circuit board 212 comprises an isolated gate driver coupled to switch actuation sensor 210. The isolated gate driver may receive actuation signals generated by switch actuation sensor 210 and control operation of a switching circuit coupled to the isolated gate driver and input/output terminals 206. For example, the isolated gate driver may open and close (or turn on and off) certain portions of the switching circuit coupled to input/output terminals 206 based on actuation signals generated by switch actuation sensor 210. In some embodiments, the switching circuit is configured to operate in, for example, a SPDT configuration. In some embodiments, circuit board 212 further comprises a power source to supply power for operating switch actuation sensor 210 and other circuitry of the circuit board 212, such as an isolated gate driver.

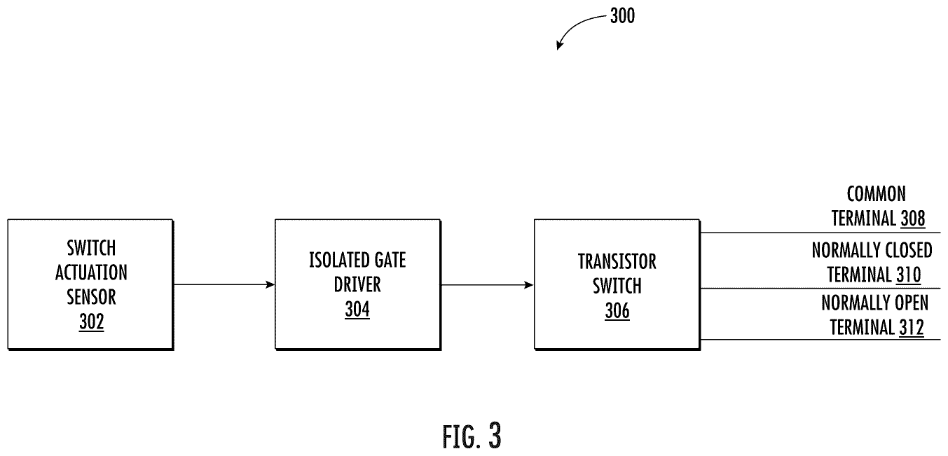

FIG. 3 is a schematic block diagram of a circuit board 300 in accordance with various embodiments of the present disclosure. Circuit board 300 is an example of the circuit board 212 associated with hybrid solid-state electrical switch 200 of FIG. 2. As depicted in FIG. 3, circuit board 300 comprises a switch actuation sensor 302, an isolated gate driver 304, and a transistor switch 306. Switch actuation sensor 302 may be configured to determine actuation or non-actuation of a mechanical device (e.g., actuation of the plunger 204) and generate actuation signals based on the determination of the actuation or non-actuation mechanical device. Switch actuation sensor 302 is coupled to isolated gate driver 304 and may transmit actuation signals to isolated gate driver 304. In some embodiments, the actuation signals generated by switch actuation sensor 302 may be received by isolated gate driver 304 as enable signals. For example, an enable signal comprising a non-zero value (e.g., positive voltage signal) may be representative of an actuation of a mechanical device, while an enable signal comprising a zero value (e.g., zero voltage signal) may be representative of non-actuation of the mechanical device.

Isolated gate driver 304 may comprise an interface for communicating actuation signals from switch actuation sensor 302 to transistor switch 306. In some embodiments, transistor switch 306 is configured to open and close circuits between a common terminal 308 and one of a normally closed terminal 310 or a normally open terminal 312. Transistor switch 306 may comprise one or more of bipolar junction transistors, integrated gate-commutated thyristors (IGCT), reverse blocking IGCTs, insulated gate bipolar transistors, MOSFETs, gate turn-off thyristors, MOSFET-controlled thyristors, silicon carbide switching devices, gallium nitride switching devices, or any other type of semiconductor-based switching device.

According to various embodiments of the present disclosure, isolated gate driver 304 is used to transfer data or power between a low-voltage circuit, such as switch actuation sensor 302, and a potentially high-voltage circuit, such as transistor switch 306. Isolated gate driver 304 may provide an electrical separation between switch actuation sensor 302 and transistor switch 306, such that there is no direct conduction path between switch actuation sensor 302 and any load circuit coupled to transistor switch 306. Accordingly, transistor switch 306 and its connections to common terminal 308, normally closed terminal 310, and normally open terminal 312 are separated by isolated gate driver 304 from switch actuation sensor 302 to isolate switch actuation sensor 302 from any voltages or currents from common terminal 308, normally closed terminal 310, and/or normally open terminal 312.

In some embodiments, isolated gate driver 304 receives actuation signals from switch actuation sensor 302 as low power enable signals. In some embodiments, the enable signals are used by the isolated gate driver 304 to control operation of the transistor switch 306. For example, the isolated gate driver 304 may generate an appropriate current gate drive to transistor switch 306 based on enable signals. In some example embodiments, an enable signal comprising a high logic value (e.g., positive or non-zero) may cause isolated gate driver 304 to control current in a manner that causes transistor switch 306 to drive the normally open terminal 312 with common terminal 308, while maintaining normally closed terminal 310 in an open circuit state. Conversely, in some example embodiments, an enable signal comprising a low logic value (e.g., zero) may cause isolated gate driver 304 to control current in a manner that causes transistor switch 306 to drive the normally closed terminal 310 with common terminal 308, while maintaining normally open terminal 312 in an open circuit state.

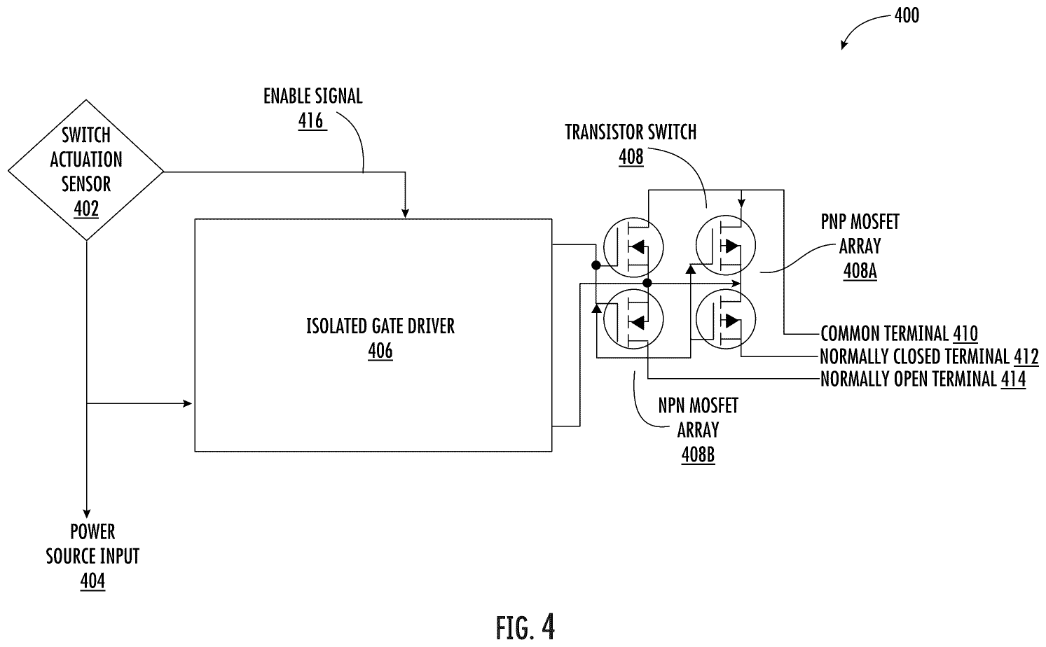

FIG. 4 is a schematic diagram of a hybrid solid-state electrical switch 400 in accordance with various embodiments of the present disclosure. As depicted in FIG. 4, hybrid solid-state electrical switch 400 comprises a switch actuation sensor 402. In some embodiments, switch actuation sensor 402 comprises a sensor that is configured to determine actuation or non-actuation of hybrid solid-state electrical switch 400. According to various embodiments of the present disclosure, hybrid solid-state electrical switch 400 is actuated by a mechanical device, such as a plunger. Based on a configuration of the mechanical device, switch actuation sensor 402 generates the enable signal 416 to a isolated gate driver 406 based on an actuation status of the mechanical device. For example, enable signal 416 may comprise (i) a low value when hybrid solid-state electrical switch 400 is not actuated, or (ii) a high value when hybrid solid-state electrical switch 400 is actuated.

The power source input 404 provides power, e.g., 5 volts direct current, to switch actuation sensor 402 and isolated gate driver 406. In some embodiments, power source input 404 comprises a power supply that is external to hybrid solid-state electrical switch 400. In some other embodiments, power source input 404 comprises a battery, for example, incorporated within hybrid solid-state electrical switch 400.

Operation of isolated gate driver 406 may vary based on enable signal 416. In some embodiments, isolated gate driver 304 generates and controls current direction of transistor switch 306 based on enable signal 416. As depicted in FIG. 4, the transistor switch 408 comprises a PNP MOSFET array 408A and a NPN MOSFET array 408B that are configured in opposite bias to implement SPDT switch functionality. In some embodiments, transistor switch 408 is configured as a SPDT switch between a common terminal 410, a normally closed terminal 412, and a normally open terminal 414. In some embodiments, isolated gate driver 406 is configured to simultaneously turn one of PNP MOSFET array 408A or NPN MOSFET array 408B on and the other off, due to their opposite bias configuration thereby achieving a SPDT circuitry mechanism.

In some example embodiments, when enable signal 416 comprises a low value (no actuation), isolated gate driver 406 turns on PNP MOSFET array 408A by applying voltage from power source input 404 to PNP MOSFET array 408A. Isolated gate driver 406 may also cause an electrical current to flow in a direction allowed by and through PNP MOSFET array 408A such that a connection between common terminal 410 and normally closed terminal 412 is generated. The current flow allowed by PNP MOSFET array 408A will not be allowed to flow through NPN MOSFET array 408B.

In some example embodiments, when enable signal 416 comprises a high value (actuation), isolated gate driver 406 turns on NPN MOSFET array 408B by applying voltage from power source input 404 to NPN MOSFET array 408B and causes an electrical current to flow in a direction allowed by and through NPN MOSFET array 408B, thereby generating a connection between common terminal 410 and normally open terminal 414. The current flow allowed by NPN MOSFET array 408B will not be allowed to flow through PNP MOSFET array 408A.

It is to be understood that the disclosure is not to be limited to the specific embodiments disclosed, and that modifications and other embodiments are intended to be included within the scope of the appended claims. Although specific terms are employed herein, they are used in a generic and descriptive sense only and not for purposes of limitation, unless described otherwise.

What is claimed is:

1. A hybrid solid-state electrical switch comprising:
a plunger;
a switch actuation sensor configured to (i) determine actuation or non-actuation of the plunger and (ii) generate one or more actuation signals based on the determined actuation or non-actuation;
one or more input/output terminals; and,
a switching circuit that is configured to perform switching operations on the one or more input/output terminals based on the one or more actuation signals.

2. The hybrid solid-state electrical switch of claim 1, wherein the switching operations are associated with a single pole, double throw switch.

3. The hybrid solid-state electrical switch of claim 1, wherein the one or more input/output terminals comprise a common input voltage and one or more electrical loads.

4. The hybrid solid-state electrical switch of claim 3, wherein the one or more electrical loads comprise a normally closed-circuit load and a normally open circuit load.

5. The hybrid solid-state electrical switch of claim 4, wherein the switching circuit is configured to:
direct the common input voltage to the normally closed-circuit load based on the one or more actuation signals comprising a signal representative of the plunger being unactuated; and,
direct the common input voltage to the normally open circuit load based on the one or more actuation signals comprising a signal representative of the plunger being actuated.

6. A hybrid solid-state electrical switch comprising:
a plunger;
a switch actuation sensor configured to (i) determine actuation or non-actuation of the plunger and (ii) generate one or more actuation signals based on the determined actuation or non-actuation;
one or more input/output terminals;
a switching circuit that is configured to perform switching operations on the one or more input/output terminals; and,
an isolated gate driver coupled to the switching circuit, the isolated gate driver is configured to (i) receive the one or more actuation signals and (ii) control operation of the switching circuit based on the one or more actuation signals.

7. The hybrid solid-state electrical switch of claim 6, wherein the switch actuation sensor is configured to determine the actuation or non-actuation of the plunger based on optical or electromagnetic changes caused by movement of the plunger an unactuated position to an actuated position.

8. The hybrid solid-state electrical switch of claim 6, wherein the switch actuation sensor comprises an infrared sensor, a photodetector sensor, or an optical sensor.

9. The hybrid solid-state electrical switch of claim 6, wherein the switch actuation sensor comprises a Hall-effect-based sensor or an anisotropic magnetoresistance sensor.

10. The hybrid solid-state electrical switch of claim 6, wherein the isolated gate driver is configured to open and close one or more portions of the switching circuit based on the one or more actuation signals.

11. A hybrid solid-state electrical switch comprising:
a switch actuation sensor configured to (i) determine actuation or non-actuation of a mechanical device and (ii) generate one or more actuation signals based on the determination of the actuation or non-actuation;
an isolated gate driver configured to generate a gate drive based on the one or more actuation signals;
a common terminal, a normally closed terminal, and a normally open terminal; and,
a transistor switch coupled to the common terminal, the normally closed terminal, and the normally open terminal, the transistor switch is configured to open and close one or more circuits between the common terminal and one of the normally closed terminal or the normally open terminal based on the gate drive.

12. The hybrid solid-state electrical switch of claim 11, wherein the one or more actuation signals are associated with an enable signal comprising a non-zero value that is representative of an actuation of the mechanical device.

13. The hybrid solid-state electrical switch of claim 11, wherein the one or more actuation signals are associated with an enable signal comprising a zero value that is representative of a non-actuation of the mechanical device.

14. The hybrid solid-state electrical switch of claim 11, wherein the transistor switch comprises one or more of bipolar junction transistors, integrated gate-commutated thyristors (IGCT), reverse blocking IGCTs, insulated gate bipolar transistors, metal-oxide-semiconductor field-effect transistors (MOSFETs), gate turn-off thyristors, MOSFET-controlled thyristors, silicon carbide switching devices, or gallium nitride switching devices.

15. The hybrid solid-state electrical switch of claim 11, wherein the isolated gate driver is configured to cause the transistor switch to drive the normally open terminal with the common terminal based on the one or more actuation signals comprising a non-zero value.

16. The hybrid solid-state electrical switch of claim 11, wherein the isolated gate driver is configured to cause the transistor switch to drive the normally closed terminal with the common terminal based on the one or more actuation signals comprising a zero value.

17. The hybrid solid-state electrical switch of claim 11, wherein the transistor switch comprises a PNP MOSFET array and a NPN MOSFET array.

18. The hybrid solid-state electrical switch of claim 17, wherein the PNP MOSFET array and the NPN MOSFET array are configured in opposite bias.
